(19) United States
(12) Patent Application Publication
(10) Pub. No.: US 2024/0337678 A1
(43) Pub. Date: Oct. 10, 2024

(54) PROBE CARD AND CALIBRATION METHOD FOR PROBER

(71) Applicant: United Microelectronics Corp., Hsinchu (TW)

(72) Inventor: Huan-Chen Peng, Hsinchu County (TW)

(73) Assignee: United Microelectronics Corp., Hsinchu (TW)

(21) Appl. No.: 18/319,507

(22) Filed: May 18, 2023

(30) Foreign Application Priority Data
Apr. 10, 2023 (TW) 112113332

(51) Int. Cl. G01R 1/073; G01R 31/26; G01R 31/28

(52) U.S. Cl. CPC G01R 1/07314; G01R 31/2601; G01R 31/2886

(57) ABSTRACT

A probe card is provided. The probe card includes a circuit board, a base board and a plurality of probing tips. The base board is disposed on the circuit board, wherein the base board includes at least three probe regions respectively disposed at at least three corners of the base board. The plurality of probing tips are disposed on the base board and electrically connected with the circuit board.

### CROSS-REFERENCE TO RELATED APPLICATION

This application claims the priority benefit of Taiwan application serial no. 112113332, filed on Apr. 10, 2023. The entirety of the above-mentioned patent application is hereby incorporated by reference herein and made a part of this specification.

### BACKGROUND

### Technical Field

The present invention relates to a probe card and a method for calibrating a prober, and in particular to a probe card and a method for calibrating a prober which can be used to calibrate the planarity of the prober.

### Description of Related Art

With the development of semiconductor technology, integrated circuit (IC) devices have been gradually miniaturized and their functions have been continuously increased. Testing of IC devices plays an important role in IC manufacturing to ensure the functionality of the IC devices. Generally speaking, a probe card is installed on the prober, so that the probe card can contact the device-under-test (DUT) placed on the chuck and provide test signals. Therefore, the planarity of the prober will affect the test results. However, in the current planarity calibration method, not only each machine needs to be re-adjusted the planarity even using the same probe card, which is time and labor-consuming, but also the risk of abnormal problems such as light or heavy needle pressure and overkill exists.

### SUMMARY

The invention provides a probe card, which can be used to calibrate the planarity of a prober.

The present invention also provides a method for calibrating the prober, which can precisely adjust the planarity of the prober by using the probe card through the electrical measurement method.

The probe card of the present invention includes a circuit board, a base board and a plurality of probing tips. The base board is disposed on the circuit board, wherein the base board includes at least three probe regions respectively disposed at at least three corners of the base board. The plurality of probing tips are disposed on the base board and electrically connected with the circuit board.

In an embodiment of the probe card of the present invention, the material of the base board includes an insulating material.

In an embodiment of the probe card of the present invention, the insulating material includes polyimide or epoxy resin.

In an embodiment of the probe card of the present invention, the area of the base board is between 4 cm² and 4,356 cm².

In an embodiment of the probe card of the present invention, the shape of the base board is quadrilateral.

In an embodiment of the probe card of the present invention, the shape of the base board is square.

In an embodiment of the probe card of the present invention, each of the at least three probe regions includes at least two probing tips of the plurality of probing tips.

In an embodiment of the probe card of the present invention, one of the at least two probing tips in each of the at least three probe regions is grounded.

The method for calibrating the prober of the present invention includes the following steps. A first probe card is provided, wherein the first probe card includes a circuit board, a base board and a plurality of first probing tips. The base board is disposed on the circuit board, wherein the base board includes at least three probe regions respectively disposed at at least three corners of the base board. The plurality of first probing tips are disposed on the base board and electrically connected with the circuit board, wherein each of the at least three probe regions includes at least two first probing tips of the plurality of first probing tips. A planarity calibration process is performed on the prober through the first probe card based on a plurality of first test signals corresponding to the plurality of first probing tips.

In an embodiment of the method for calibrating the prober of the present invention, the step of performing the planarity calibration process on the prober though the first probe card based on the plurality of first test signals corresponding to the plurality of first probing tips includes: performing a first test step to obtain a first set of the first test signals of the plurality of first test signals; and adjusting a planarity of the prober based on the first set of the first test signals of the plurality of first test signals.

In an embodiment of the method for calibrating the prober of the present invention, the step of performing the planarity calibration process on the prober though the first probe card based on the plurality of first test signals corresponding to the plurality of first probing tips further includes: performing a second test step to obtain a second set of the first test signals of the plurality of first test signals to confirm the planarity of the prober.

In an embodiment of the method for calibrating the prober of the present invention, during the first test step and the second test step, the plurality of first probing tips in the first probe card are in contact with the object under test on the chuck of the prober.

In an embodiment of the method for calibrating the prober of the present invention, the plurality of first test signals are provided by a tester electrically connected with the first probe card.

In an embodiment of the method for calibrating the prober of the present invention, the plurality of first test signals are open-short signals.

In an embodiment of the method for calibrating the prober of the present invention, after performing the planarity calibration process, the method further includes: providing a second probe card, including a plurality of second probing tips; and performing a third test step to obtain a plurality of second test signals corresponding to the plurality of second probing tips to perform a planarity verification process on the prober.

To sum up, the probe card of the present invention can be used to calibrate the planarity of the prober by arranging at least three probe regions respectively located at at least three corners of the base board. In this way, the method for calibrating the prober of the present invention can accurately adjust the planarity of the prober by means of electrical measurement method, and the adjusted planarity can meet the actual planarity during the testing of various current probe cards. Thereby, the processing time for planarity abnormality can be saved and the problem of overkill and crushing of the object under test (such as wafer) caused by planarity abnormality can be avoided.

In order to make the above-mentioned features and advantages of the present invention more comprehensible, the following specific embodiments are described in detail with reference to the accompanying drawings.

### BRIEF DESCRIPTION OF THE DRAWINGS

FIG. 1 is a top view of a probe card according to an embodiment of the present invention.

FIG. 2 is a top view of a probe card according to another embodiment of the present invention.

FIG. 3 is a flowchart of a method for calibrating a prober according to an embodiment of the present invention.

FIG. 4 is a schematic cross-sectional view of a structure when performing a planarity

calibration process according to an embodiment of the present invention.

FIG. 5 is a schematic cross-sectional view of a structure when performing a planarity verification process according to an embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “under” mentioned in the text are only used to refer to the direction of the drawings, and are not used to limit the present invention. Thus, it should be understood that “on” can be used interchangeably with “under” and that when an element such as a layer or film is placed “on” another element, the element may be placed directly on the other element, or there may be additional element between the element and the another element. On the other hand, when an element is said to be placed “directly on” another element, there is no intervening element present between the two elements.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

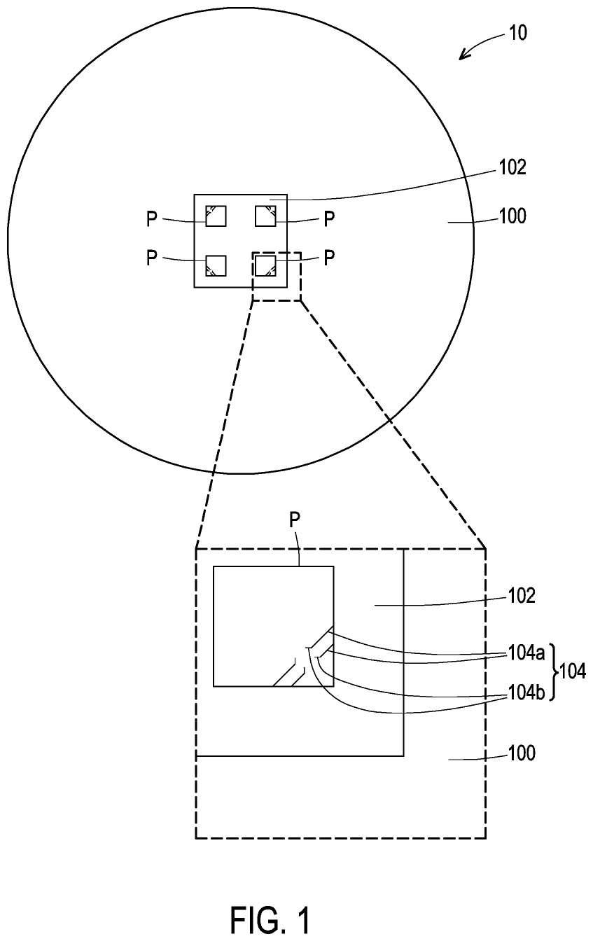

FIG. 1 is a top view of a probe card according to an embodiment of the present invention. Referring to FIG. 1, the probe card 10 of this embodiment includes a circuit board 100, a base board 102. and a plurality of probing tips 104. However, the probe card 10 of the present invention is not limited to the one shown in FIG. 1. In detail, anyone of ordinary skill in the art should understand that the probe card 10 may also include other components such as a pin base (not shown), a space transformer board (not shown) through the following description of the probe card 10.

The circuit board 100 may be or include a printed circuit board (PCB), and the printed circuit board is provided with a circuit layout (not shown). The printed circuit board may be any printed circuit board known to those skilled in the art. For example, the printed circuit board may be provided with conductive lines, conductive pads, conductive vias, plated through holes. and the like. In this embodiment, as shown in FIG. 1, the shape of the circuit board 100 is circular. However, the present invention is not limited thereto. In other embodiments, the shape of the circuit board 100 may be a rectangle or other polygons.

The base board 102 is disposed on the circuit board 100. The material of the base board 102 include an insulating material. In this embodiment, the insulating material includes polyimide or epoxy resin. The area of the base board 102 is between 4 cm² and 4,356 cm².

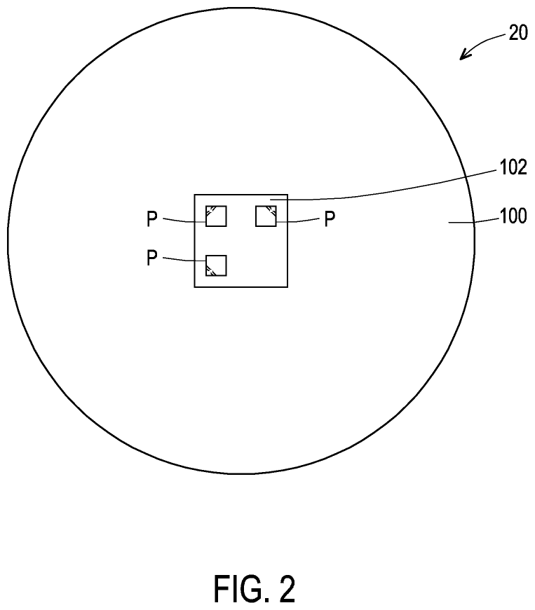

As shown in FIG. 1, in this embodiment, the base board 102 includes four probe regions P, which are respectively arranged at four corners of the base board 102. However, the present invention is not limited thereto. In other embodiments, the base board 102 may include three probe regions P, five probe regions P or more than five probe regions P, which are respectively arranged at the corners of the base board 102. That is to say, the base board 102 includes at least three probe regions respectively arranged at at least three corners of the base board 102, which falls within the scope of the present invention. For example, as shown in FIG. 2, in the probe card 20, the base board 102 includes three probe regions P, which are respectively arranged at three corners of the base board 102.

In addition, as shown in FIG. 1, in this embodiment, the shape of the base board 102 is a square. However, the present invention is not limited thereto. In other embodiments, the shape of the base board 102 may be other quadrilateral (such as rectangle, trapezoid, etc.), or other polygon (such as triangle, pentagon, etc.).

The plurality of probing tips 104 are disposed on the base board 102. Each probing tip 104 is made of conductive material. As shown in FIG. 1, in this embodiment, each probing tip 104 has a cantilever part 104a and a needle tip part 104b connected with each other, and the needle tip part 104b is used to touch the object under test. That is to say, in this embodiment, the probe card 10 is a cantilever-type probe card. However, the present invention is not limited thereto. In other embodiments, the probe card 10 may also be a vertical-type probe card. In addition, the plurality of probing tips 104 are electrically connected with the circuit board 100. For example, the plurality of probing tips 104 may be electrically connected with the circuit board 100 through wire bonding (not shown). However, the present invention is not limited thereto, and the plurality of probing tips 104 may be electrically connected with the circuit board 100 through any connection/bonding method known to those skilled in the art.

As shown in FIG. 1, in this embodiment, each probe region P includes four probing tips 104. However, the present invention is not limited thereto, and it should be understood that each probe region P may include any number of probing tips 104. In detail, each probe region P includes at least two probing tips 104, and one of the at least two probing tips 104 is grounded.

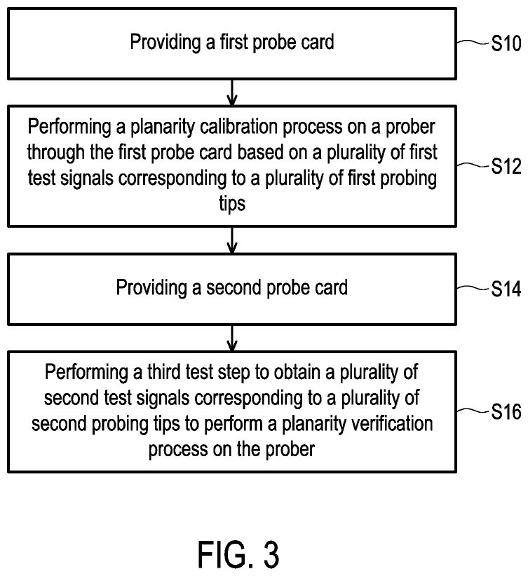

For the probe card 10, the probe card 10 can be used to calibrate the planarity of the prober by arranging at least three probe regions (for example, four probe regions P) respectively located at the corners of the base board 102. Hereinafter, the method for calibrating the prober provided by the present invention will be described with reference to FIG. 3 to FIG. 5.

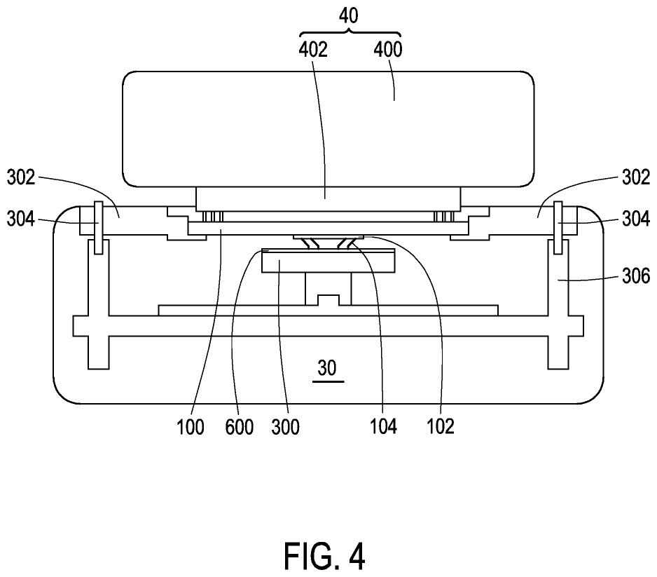

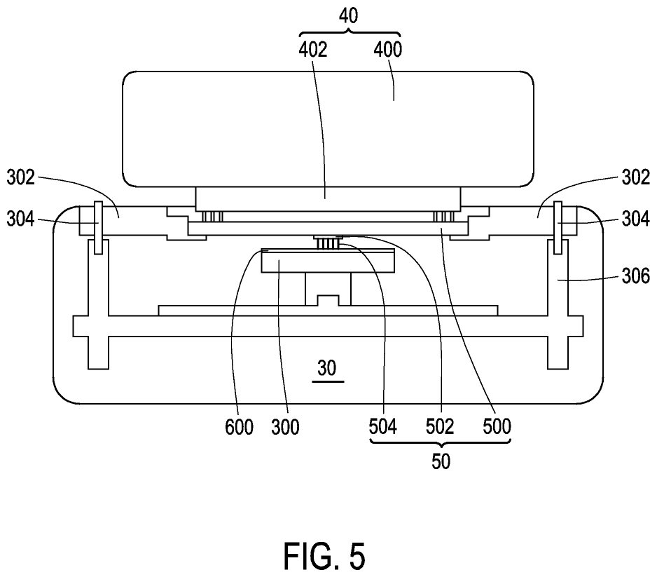

FIG. 3 is a flowchart of a method for calibrating a prober according to an embodiment of the present invention. FIG. 4 is a schematic cross-sectional view of a structure when performing a planarity calibration process according to an embodiment of the present invention. FIG. 5 is a schematic cross-sectional view of a structure when performing a planarity verification process according to an embodiment of the present invention.

Please refer to FIG. 3, firstly, step S10 is performed to provide a first probe card. In detail, in this embodiment, the first probe card includes any probe card 10, 20 in the foregoing embodiments. The relevant descriptions of the probe cards 10 and 20 have been described in detail above, so they will not be repeated here. Before performing the subsequent steps, the planarity of the plurality of probing tips 104 in the probe cards 10, 20 is calibrated using the PRVX tester. In one embodiment, the planarity of the plurality of probing tips 104 calibrated by the PRVX tester is between ±2.5 μm.

Next, proceed to step S12, a planarity calibration process is performed on the prober through using the first probe card (for example: the probe card 10, 20) based on a plurality of first test signals corresponding to the plurality of first probing tips (for example: the plurality of probing tips 104).

Please refer to FIG. 4, during the planarity calibration process, firstly, the probe card 10 or the probe card 20 is placed on a plate holder 302 of a prober 30. In this embodiment, viewed from a top view direction above the prober 30, the plate holder 302 of the prober 30 is in the shape of a ring. As shown in FIG. 4, in the prober 30, the plate holder 302 is fixed to a support frame 306 through a plurality of fasteners 304. In one embodiment, the fastener 304 includes a screw and a corresponding nut. For example, the plate holder 302 and the support frame 306 each include receiving holes at desired locations so that the screws may be screwed through the receiving holes of the plate holder 302 and the support frame 306 to affix the plate holder 302 onto the support frame 306. For example, the receiving holes of the plate holder 302 and the support frame 306 are threaded holes, and the screws are engaged with the plate holder 302 and the support frame 306 in a threaded manner. However, the present invention is not limited thereto, and other suitable fixing manner may also be used, as long as the plate holder 302 can be stably engaged with the support frame 306. In addition, the planarity of the plate holder 302 may be adjusted by adjusting each fastener 304 (for example, tightening or loosening).

Next, a tester 40 is electrically connected with the probe card 10 or the probe card 20. As shown in FIG. 4, the tester 40 includes a test head 400 and a pogo tower 402 disposed on the test head 400, and the test head 400 is electrically connected with the probe card 10 or the probe card 20 through the pogo tower 402. In detail, as shown in FIG. 4, the pogo tower 402 is electrically connected with the circuit board 100.

From another point of view, the probe card 10 or the probe card 20 is disposed between the tester 40 and the object under test, and is used to transmit the test signals of the tester 40 to the object under test. That is to say, through the probe card 10 or the probe card 20, the tester 40 can test the object under test to provide the test signals. For example, the tester 40 includes an electrical test circuit for providing test signals and collecting test results from the object under test. In this embodiment, the tester 40 includes a computer-based control system to control the test and analyze the test results.

After the tester 40 is electrically connected with the probe card 10 or the probe card 20, the first test step is performed to obtain a first set of first test signals among the plurality of first test signals. Specifically, after adjusting the chuck 300 of the prober 30 so that the plurality of probing tips 104 in the probe card 10 or the probe card 20 are in contact with the object under test 600 on the chuck 300, the first test step is performed. Further, during the first test step, the planarity of the probe card 10 or the probe card 20 is poor, so that some of the probing tips 104 are not in contact with the object under test 600 on the chuck 300, therefore when the tester 40 analyzes the obtained first set of first test signals, it will display fail signals corresponding to the said some of the probing tips 104. In this embodiment, the first test signal is an open-short signal. Generally speaking, when testing the object under test, the planarity of the probe card will affect the value of the over drive. When the planarity of the probe card is poor, the over drive must be increased. In some embodiments, the over drive during the first test step is between about −15 μm and about 20 μm.

Then, the planarity of the prober 30 is adjusted based on the obtained first set of the first test signals. Specifically, the planarity of the prober 30 is adjusted according to the fail signals displayed by the tester 40. For example, in FIG. 4, when the probing tips 104 on the left cannot be in contact with the object under test 600 on the chuck 300 and the tester 40 displays the corresponding fail signals, the fastener 304 on the left can be adjusted accordingly (for example, tightened) to adjust the planarity of the plate holder 302.

After adjusting the planarity of the prober 30 (for example, the planarity of the plate holder 302), a second test step is performed to obtain a second set of the first test signals among the plurality of first test signals to confirm the planarity of the prober 30. The second test step is performed in the same manner as the first test step. Specifically, after adjusting the chuck 300 of the prober 30 so that the plurality of probing tips 104 in the probe card 10 or probe card 20 are in contact with the object under test 600 on the chuck 300, the second test step is performed to obtain the second set of first test signals, and the planarity of the prober 30 is confirmed by the signals displayed after the tester 40 analyzes the obtained second set of the first test signals. In some embodiments, if the difference between the over drive during the second test step and the over drive during the first test step is less than or equal to 5 μm, the operation of the planarity calibration process is terminated. However, if the difference between the over drive during the second test step and the over drive during the first test step is still greater than 5 μm, and the tester 40 still displays obvious fail signals after analyzing the obtained second set of the first test signals, then, after adjusting the planarity of the prober 30 again based on the obtained second set of the first test signals, the second test step is performed again until it is confirmed that the prober 30 reaches the desired planarity.

Based on the above, in the method for calibrating the prober of the present invention, the planarity of the prober 30 can be precisely adjusted by using the probe card 10 or the probe card 20 through the electrical measurement method, thereby saving the processing time for planarity abnormality. From another point of view, because the planarity of the prober 30 is adjusted through the probe card 10 or the probe card 20, the prober 30 during performing the planarity calibration process is in the state in which the prober 30 is used for probing the object under test (such as a wafer) (that is, the tester 40 is placed on the prober 30 to be electrically connected with the probe card 10 or the probe card 20). In this way, through the method for calibrating the prober of the present invention, the adjusted planarity of the prober 30 can conform to the actual planarity during the testing of various current probe cards. From another point of view, since on the base board 102 of the probe card 10 or the probe card 20, the at least three probe regions respectively located at the corners of the base board 102 can constitute a surface, the planarity of the adjusted prober 30 through the method for calibrating the prober of the present invention can meet the planarity required by various current probe cards. Further, the area of the base board 102 of the probe card 10 or the probe card 20 is between 4 cm² and 4,356 cm², so that the planarity of the prober 30 adjusted by the method for calibrating the prober of the present invention can meet the planarity required by various current probe cards. Hereinafter, step S14 and step S16 will be performed to verify the planarity of the prober 30.

Next, referring to FIG. 3 and FIG. 5, step S14 is performed to provide a second probe card 50. In this embodiment, the second probe card 50 may be any conventional probe card known to those skilled in the art for testing wafers. As shown in FIG. 5, the second probe card 50 includes a circuit board 500, a base board 502, and a plurality of probing tips 504. However, anyone of ordinary skill in the art should can understand that the second probe card 50 of the present invention is not limited to the one shown in FIG. 5. In detail, the second probe card 50 may also include other components such as a pin base (not shown), a space transformer board (not shown).

The circuit board 500 may be the same as the circuit board 100 previously described with respect to FIG. 1. The relevant description of the circuit board 100 has been described in detail above, so it will not be repeated here. The base board 502 of this embodiment is similar to the base board 102 previously described with respect to FIG. 1, except that the base board 502 has only one probe region. The relevant description of the base board 102 has been described in detail above, so it will not be repeated here. The probing tip 504 of this embodiment is similar to the probing tip 104 previously described with respect to FIG. 1, except that it is straight. That is to say, in this embodiment, the second probe card 50 is a vertical-type probe card. The relevant description of the probing tip 104 has been described in detail above, so it will not be repeated here.

Likewise, before performing the subsequent steps, the planarity of the plurality of probing tips 504 in the second probe card 50 is calibrated using the PRVX tester. In this way, the probe cards 10, 20 for performing the planarity calibration process on the prober 30 and the second probe card 50 use a single calibration source to calibrate the planarity. In one embodiment, the planarity of the plurality of probing tips 504 calibrated by the PRVX tester is between ±5 μm.

Finally, step S16 is performed, and a third test step is performed to obtain a plurality of second test signals corresponding to the plurality of second probing tips 504 to perform a planarity verification process on the prober 30.

Please refer to FIG. 5, during the planarity verification process, firstly, the second probe card 50 is placed on the plate holder 302 of the prober 30. Next, the tester 40 is electrically connected with the second probe card 50. As shown in FIG. 5, the test head 400 of the tester 40 is electrically connected with the second probe card 50 through the pogo tower 402. In detail, as shown in FIG. 5, the pogo tower 402 is electrically connected with the circuit board 500.

From another point of view, the second probe card 50 is disposed between the tester 40 and the object under test, and is used to transmit the test signals of the tester 40 to the object under test. That is to say, through the second probe card 50, the tester 40 can test the object under test to provide the test signals.

After the tester 40 is electrically connected with the second probe card 50, the third test step is performed to obtain the plurality of second test signals. The third test step is performed in the same manner as the first test step. In detail, after adjusting the chuck 300 of the prober 30 so that the plurality of probing tips 504 in the second probe card 50 are in contact with the object under test on the chuck 300, the third test step is performed to obtain the plurality of second test signals, and the planarity of the prober 30 is verified through the signals displayed after the tester 40 analyzes the obtained the plurality of second test signals. In this embodiment, the second test signal is also an open-short signal. In some embodiments, the difference between the over drive during the third test step and the over drive when the calibration is not performed yet by using the first probe card is less than about 20 μm, which means the planarity of the adjusted and verified prober 30 can meet the planarity required by various current probe cards.

As can be seen from the above, in the method for calibrating the prober of the present invention, the planarity of the prober 30 can be precisely adjusted by using the probe card (such as the probe card 10, 20) of the present invention, and the adjusted planarity can conform to the actual planarity during the testing of various current probe cards, and thereby the problem of overkill and crushing of the object under test (such as wafer) caused by planarity abnormality can be avoided, and the overall processing time for planarity abnormality can be saved.

Although the invention has been described with reference to the above embodiments, it will be apparent to one of the ordinary skills in the art that modifications to the described embodiment may be made without departing from the spirit of the invention. Accordingly, the scope of the invention will be defined by the attached claims not by the above detailed descriptions.

What is claimed is:

1. A probe card, comprising:
a circuit board;
a base board, disposed on the circuit board, wherein the base board includes at least three probe regions respectively disposed at at least three corners of the base board; and
a plurality of probing tips, disposed on the base board and electrically connected with the circuit board.

2. The probe card according to claim 1, wherein a material of the base board includes an insulating material.

3. The probe card according to claim 2, wherein the insulating material includes polyimide or epoxy resin.

4. The probe card according to claim 1, wherein an area of the base board is between 4 cm² and 4,356 cm².

5. The probe card according to claim 1, wherein a shape of the base board is quadrilateral.

6. The probe card according to claim 5, wherein the shape of the base board is square.

7. The probe card according to claim 1, wherein each of the at least three probe regions includes at least two probing tips of the plurality of probing tips.

8. The probe card according to claim 7, wherein one of the at least two probing tips in each of the at least three probe regions is grounded.

9. A calibration method for a prober, comprising:
providing a first probe card, wherein the first probe card comprises:
a circuit board;
a base board, disposed on the circuit board, wherein the base board includes at least three probe regions respectively disposed at at least three corners of the base board; and
a plurality of first probing tips, disposed on the base board and electrically connected with the circuit board, wherein each of the at least three probe regions includes at least two first probing tips of the plurality of first probing tips; and
performing a planarity calibration process on the prober through the first probe card based on a plurality of first test signals corresponding to the plurality of first probing tips.

10. The calibration method for the prober according to claim 9, wherein the step of performing the planarity calibration process on the prober though the first probe card based on the plurality of first test signals corresponding to the plurality of first probing tips includes:
performing a first test step to obtain a first set of the first test signals of the plurality of first test signals; and
adjusting a planarity of the prober based on the first set of the first test signals of the plurality of first test signals.

11. The calibration method for the prober according to claim 10, wherein the step of performing the planarity calibration process on the prober though the first probe card based on the plurality of first test signals corresponding to the plurality of first probing tips further includes:
performing a second test step to obtain a second set of the first test signals of the plurality of first test signals to confirm the planarity of the prober.

12. The calibration method for the prober according to claim 11, wherein during the first test step and the second test step, the plurality of first probing tips in the first probe card are in contact with an object under test on a chuck of the prober.

13. The calibration method for the prober according to claim 9, wherein the plurality of first test signals are provided by a tester electrically connected with the first probe card.

14. The calibration method for the prober according to claim 9, wherein the plurality of first test signals are open-short signals.

15. The calibration method for the prober according to claim 9, wherein after performing the planarity calibration process, the method further includes:
providing a second probe card, including a plurality of second probing tips; and
performing a third test step to obtain a plurality of second test signals corresponding to the plurality of second probing tips to perform a planarity verification process on the prober.
